(19) United States
(12) Patent Application Publication
(10) Pub. No.: US 2022/0007523 A1
(43) Pub. Date: Jan. 6, 2022

(54) MODULAR ENCLOSURE SYSTEM

(71) Applicant: Fairlead Integrated, LLC, Portsmouth, VA (US)

(72) Inventor: Ervin Keith Hubble, JR., Smithfield, VA (US)

(73) Assignee: Fairlead Integrated, LLC, Portsmouth, VA (US)

(21) Appl. No.: 17/361,931

(22) Filed: Jun. 29, 2021

Related U.S. Application Data
(60) Provisional application No. 63/046,745, filed on Jul. 1, 2020.

(51) Int. Cl. H05K 5/02; H05K 5/06; H05K 5/00

(52) U.S. Cl. CPC H05K 5/02; H05K 5/0004; H05K 5/061

(57) ABSTRACT

A modular enclosure system for forming a weld-free enclosure. The enclosure system includes a corner piece and a plurality of rails each adapted to mate with the corner piece and secured at one or more exterior-facing frame attachment points on the corner piece to form a frame. Panels are also included and are adapted to be secured to the frame. The panel conceals the frame attachment points when secured to the frame. Another aspect is directed to a weld-free enclosure assembled using the components of the modular enclosure system described herein.

### CROSS-REFERENCE TO RELATED APPLICATION

The following application claims priority to U.S. Provisional Application No. 63/046,745 filed Jul. 1, 2020, the disclosure of which is incorporated by reference in its entirety.

### FIELD OF THE INVENTION

The present invention relates to a modular enclosure system, and in particular, a modular enclosure system that is weld-free while remaining fully environmentally sealed.

### BACKGROUND

Enclosure systems are the primary boundary between the electrical equipment contained within and their outside environment. They serve two primary purposes: 1) to act as a safety boundary to the operators that interact with them, especially against electric shock and 2) to protect the equipment from severe environmental conditions such as high impact shock, continuous shipboard vibration, electromagnetic interference, high and low temperatures, high humidity, dust, rain, sleet, ice chemicals, etc.

Most enclosure systems on Naval Combatant ships utilize frames, skins and doors of welded construction. Welded enclosures stand up well to shipboard shock and vibration requirements. However, the weld certification process and project specific weld approvals are taking longer to receive due to the increase in Submarine Safety Program (SUBSAFE) and general welding requirements for Naval Combatants. A continually growing challenge is that increasingly larger enclosures are needed in order to handle modern integrated power and energy systems. As the enclosures get larger, it becomes more difficult to maintain tight tolerances over long distances due to material distortions introduced by the welding process.

Another challenge as enclosure systems get larger are the limitations encountered during installation and retrofit. During new construction, large assemblies can only be installed at very specific points during the ships construction as the components are too large for passageways and hatches. Likewise, during repair or modernization, hull cuts must often be made to remove large assemblies which can require hot work, not only on the hull, but also on the enclosures and foundations themselves.

With regard to aluminum enclosures, 5,000 series are generally preferred over 6,000 and 7,000 series for their greater resistance to corrosion in marine laden environments and due to their lower susceptibility to stress corrosion cracking at welded joints. For these reasons, in marine application, 6,000 and 7,000 series are prohibited from being welded. Unfortunately, this comes at the expense of strength as 5,000 series aluminum alloys have lower strength properties compared to the two higher series.

Thus, Applicant desires a modular enclosure system for forming an aluminum enclosure that is weld-free without compromising its structural strength or dimensional tolerancing in large standalone or multi-bay assemblies.

### SUMMARY

To this end, the present invention is directed to a modular enclosure system and weld-free enclosures formed thereof that provides several advantages over prior systems. For example, the modular design enables highly configurable enclosures (e.g., cabinets of various widths, lengths, depths and payload capacities) that can easily be arranged with basic structural elements. These enclosures are easily assembled/disassembled and can be further modified as needed. Moreover, removable panels on all surfaces allow easy access to internal equipment during assembly, installation and repair.

The frames are comprised of machined/extruded parts that provide high dimensional accuracy. Since the enclosures are weld-free, there is no bending or warping of the components as found in other prior art systems because of heat applied during the welding process. Thus, these weld-free enclosures have higher dimensional accuracy as compared to their welded counterparts. Furthermore, bypassing the welding approval process and using existing, prequalified structural members modified for each application expedites time to market. All these benefits and more translate into lower non-recurring and recurring costs.

Accordingly, one aspect of the present invention is directed to a modular enclosure system including a corner piece, a plurality of rails and a panel. The corner piece has a plurality of faces, and each rail is adapted to mate with a face of the corner piece. Once the corner piece and rail are mated, they are secured at one or more frame attachment points to form a frame. The panel is adapted to be secured to the frame and conceals the frame attachment points when the panel is secured. Each rail has an exterior-facing side that faces away from the frame when formed and an interior-facing side positioned within a cavity formed by the frame, whereby the fasteners securing the rails to the corner piece are positioned on the exterior-facing sides of the rails. The corner piece may be adapted to be secured to each rail on a first and second face.

Another aspect of the present invention is directed to a weld-free enclosure constructed from a modular enclosure system. The enclosure may be assembled as a standalone configuration or a multi-bay configuration. The enclosure includes one or more corner pieces, a plurality of rails mated and secured by fasteners with the corner piece to form a frame. A panel is secured to the rails and the corner piece, thereby concealing the fasteners securing the rails and the corner piece. Each rail has an exterior-facing side and an interior-facing side, wherein the exterior-facing side faces away from the frame and the interior-facing side positioned within a cavity formed by the frame. The fasteners securing the rails to each corner piece are positioned on the exterior-facing sides of the rails. In one embodiment, the corner piece has a male end and the rail has a female end whereby the rail is adapted to mate with the corner piece by inserting the male end into the female end.

These and other aspects will become apparent to those skilled in the art after a reading of the following description of the embodiments when considered with the drawings.

### BRIEF DESCRIPTION OF THE DRAWINGS

FIG. 1 is a front perspective view of an enclosure system according to one embodiment;

FIG. 2 is a front elevation view of the enclosure system in FIG. 1;

FIG. 3 is a rear elevation view of the enclosure system in FIG. 1;

FIG. 4 is a perspective view of the frame of the enclosure system in FIG. 1;

FIG. 5 is a front perspective view of the frame in FIG. 4 with a back panel and plate installed;

FIG. 6 is a front perspective view of a corner piece according to one embodiment;

FIG. 7 is a rear perspective view of the corner piece in FIG. 6;

FIG. 8 is a front perspective view of a rail according to one embodiment;

FIG. 9 is a side elevation view of the rail in FIG. 8;

FIG. 10 is an enlarged exploded view of a corner piece and a plurality of rails according to one embodiment;

FIG. 11 is an enlarged partially exploded view of a corner piece mated to a plurality of rails according to one embodiment;

FIG. 12 is an enlarged exploded view of an enclosure system according to one embodiment;

FIG. 13 is an enlarged view of the enclosure system in FIG. 12;

FIG. 14 is an enlarged perspective view of a corner piece having a groove;

FIG. 15 is an enlarged cutaway perspective view of the corner piece in FIG. 14 mated with a rail;

FIG. 16 is an enlarged perspective view of a rail according to another embodiment;

FIG. 17 is an enlarged perspective partially transparent view of a corner piece with panels mounted and a rail partially mounted;

FIG. 18 is an exploded view of an enclosure system according to another embodiment;

FIG. 19 is a perspective view of an enclosure system according to another embodiment;

FIG. 20 is a perspective view of a frame for an enclosure system according to another embodiment;

FIG. 21 is an enlarged view of the frame in FIG. 20;

FIG. 22 is an enlarged exploded view of the frame in FIG. 20;

FIG. 23 is a top perspective view of an integrated end cap of a frame for an enclosure system according to another embodiment;

FIG. 24 is a bottom perspective view of the integrated end cap in FIG. 23; and

FIG. 25 is a bottom perspective view of a set of rails and corner pieces forming an end cap of a frame for an enclosure system according to another embodiment.

### DETAILED DESCRIPTION OF THE EMBODIMENTS

The foregoing and other aspects of the present invention will now be described in more detail with respect to the description and methodologies provided herein. It should be appreciated that the invention can be embodied in different forms and should not be construed as limited to the embodiments set forth herein. Rather, these embodiments are provided so that this disclosure will be thorough and complete, and will fully convey the scope of the invention to those skilled in the art.

The terminology used in the description of the invention herein is for the purpose of describing particular embodiments only and is not intended to be limiting of the invention. As used in the description of the embodiments of the invention and the appended claims, the singular forms “a”, “an” and “the” are intended to include the plural forms as well, unless the context clearly indicates otherwise. Also, as used herein, “and/or” refers to and encompasses any and all possible combinations of one or more of the associated listed items.

As used herein, the terms “comprise,” “comprises,” “comprising,” “include,” “includes” and “including” specify the presence of stated features, integers, steps, operations, elements, and/or components, but do not preclude the presence or addition of one or more other features, integers, steps, operations, elements, components, and/or groups thereof.

All patents, patent applications and publications referred to herein are incorporated by reference in their entirety. In case of a conflict in terminology, the present specification is controlling.

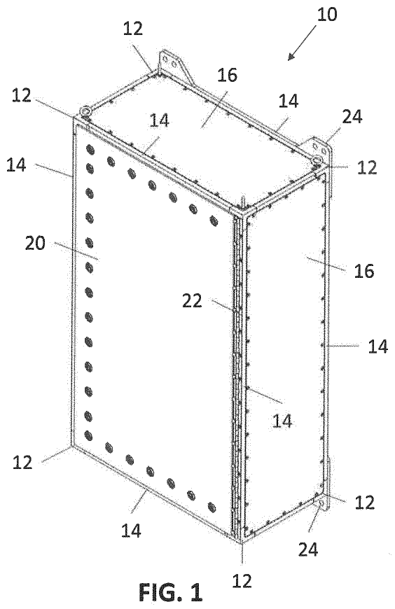

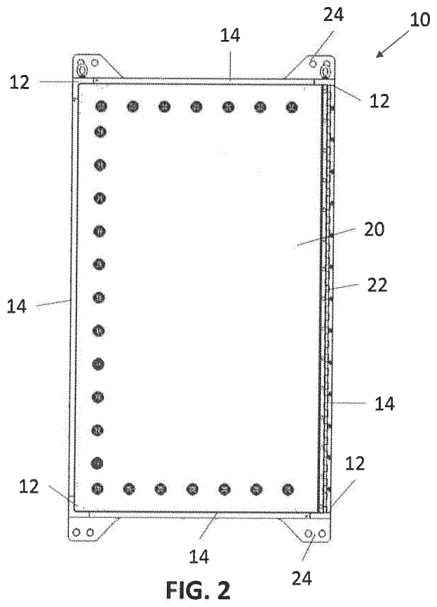

Referring now to FIGS. 1-3, a modular enclosure system 10 assembled into an enclosure is provided in accordance with one embodiment of the present invention. In the embodiment shown, the modular enclosure system 10 comprises a set of corner pieces 12 and a plurality of rails 14. Each corner piece 12 is mated to a plurality of rails 14 to form a frame. Panels 16 are provided to be secured to the frame formed by the corner pieces 12 and the rails 14 as shown in FIG. 1. The corner pieces and rails of the enclosure system may be comprised of aluminum.

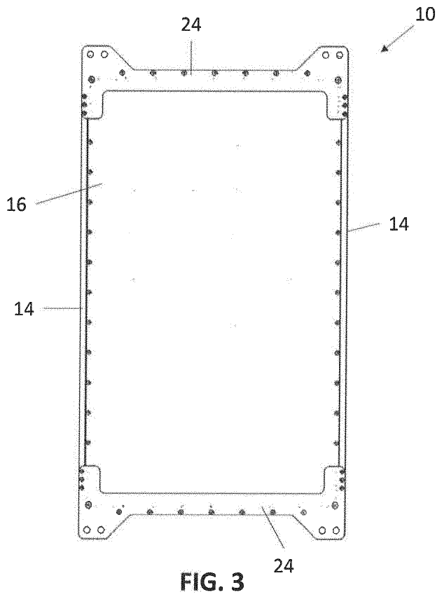

In some embodiments, the panel may be a door 20 with a hinge 22 installed on a rail 14. For example, the hinge 22 may be a piano hinge adapted to open and close the door. The enclosure system 10 may also include a mount 24 for securing the enclosure system 10 onto a surface such as a wall. As seen in FIG. 3, the mount 24 may be installed onto a rail 14 and one or more corner pieces 12.

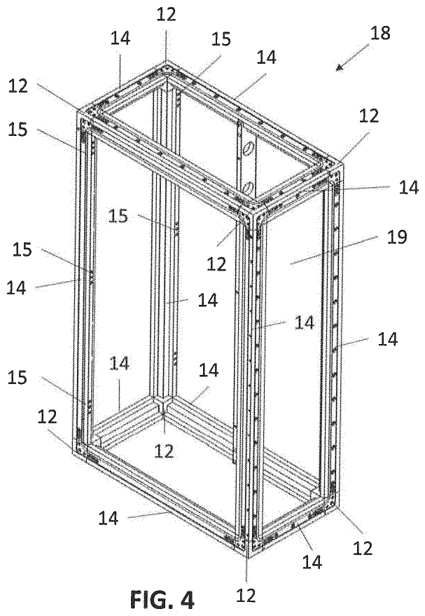

FIG. 4 provides an overview of a frame 18 formed from a plurality of rails 14 mated to a set of corner pieces 12. In the embodiment shown, the corner pieces 12 and rails 14 form a substantially rectangular frame. The enclosure system 10 includes a cavity 19 within the frame 18 for storing items.

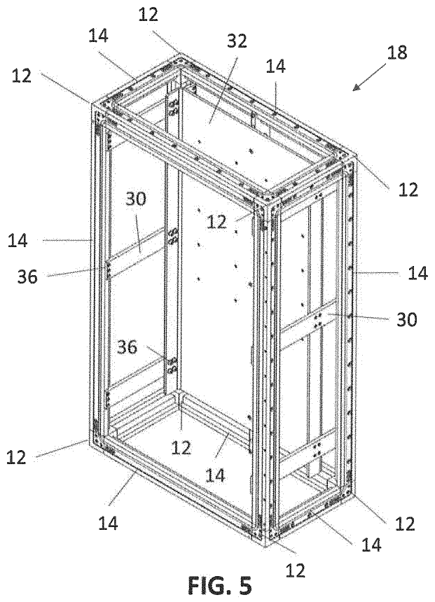

Each rail 14 further includes one or more holes 15 for mounting items within the cavity 19. As seen in FIG. 5, flat bars may be mounted as structural support members 30 onto the rails 14 with fasteners 36. An internal panel 32 may be mounted to support members 30 and ultimately to the rails 14. In some embodiments, the holes 15 may be used to mount one or more horizontal platforms to create shelves for storing items. Items to be stored within the cavity 19 may include equipment, such as but not limited to power distribution, conversion and energy storage solutions (e.g., switchboards, junction boxes, variable speed drives, energy magazines, etc.).

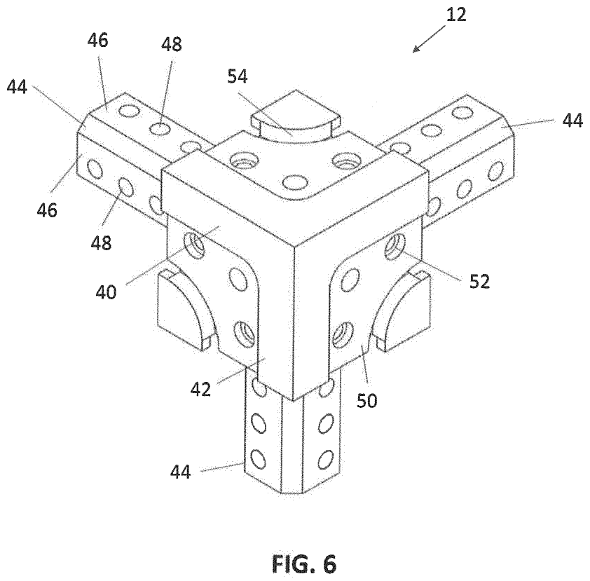

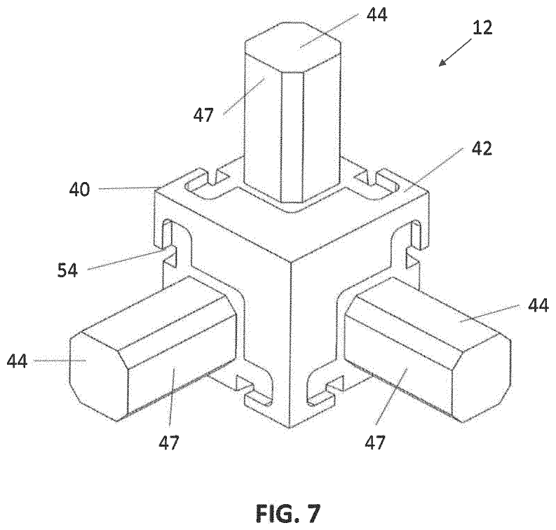

The corner piece 12 may have one or male ends, each adapted to be inserted into a female end of a rail 14. One embodiment of a corner piece 12 is shown in FIGS. 6 and 7. The corner piece 12 is comprised of a central block 40. One or more faces 42 of the central block 40 include a post 44 serving as male end to be inserted into a female end of a rail 14. The posts 44 may be positioned at right angles to one another. In other embodiments, some or all of the posts 44 may be positioned at acute or obtuse angle with respect to each other.

Each post 44 has exterior-facing sides 46 and interior-facing sides 47. The interior-facing sides 47 are positioned within the cavity 19 formed by the frame 18 and are not exposed to the exterior when the enclosure system 10 is assembled. Frame attachment points 48 are positioned on the exterior-facing sides 46 of each post 44. Fasteners are installed at the frame attachment points 48 to secure the rail 14 to the post 44 once mated.

One or more faces 42 of the central block 40 that are unoccupied by posts 44 may include a recess 50 for receiving a corner of a panel 16. The recess 50 includes one or more panel attachment points 52 for securing the corner of the panel 16 inserted into the recess 50. A slot 54 is included in the recess 40 for receiving a sealing feature to shield the cavity 19 from environmental elements and electromagnetic interference (EMI).

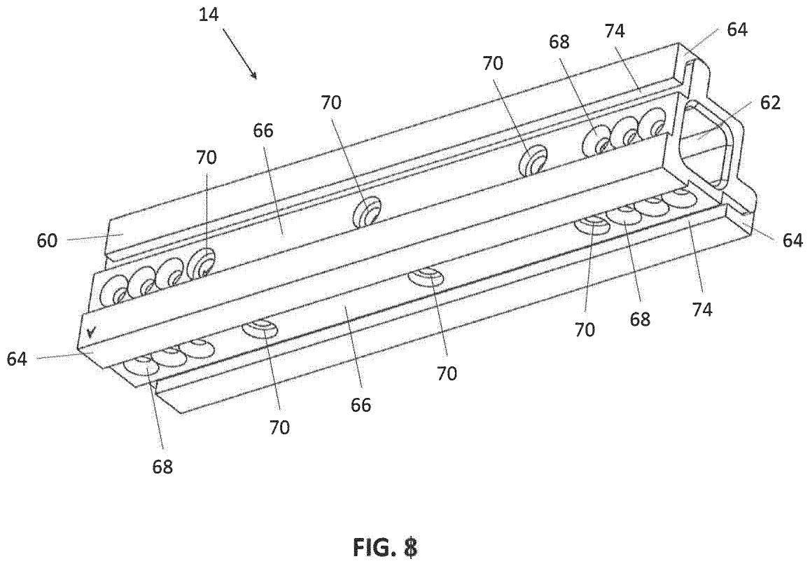

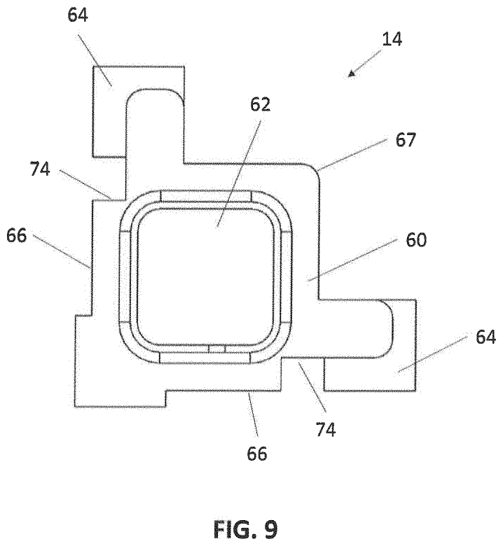

FIGS. 8 and 9 depict one embodiment of a rail 14. In this embodiment, the rail 14 comprises an elongated member 60 with an opening 62 at one or both opposing ends. The opening 62 operates as a female end for receiving the male end of a corner piece 12. The elongated member 60 may be hollow. In alternative embodiments, the elongated member 60 may be substantially solid with openings 62 at one or both opposing ends.

The elongated member 60 further includes a set of appendages 64 that are orthogonal to one another. The set of appendages 64 may form one or more recesses 66 on the elongated member 60 for receiving an edge of a panel 16. The recesses 66 for receiving the edge of the panel 16 are exterior-facing, wherein exterior-facing is defined as facing away from the frame 18 when assembled and being exposed on the exterior of the frame 18 when the panels 16 are not installed. The interior-facing side 67 of the elongated member may include interior holes 15 (as shown in FIG. 4) for mounting items within the cavity 19. The items mounted may include, but is not limited to, structural support members, interior panels, shelving and equipment to be stored within the cavity 19.

As defined herein, exterior-facing and interior-facing is in reference to the frame 18 and cavity 19, not the component itself. For example, one embodiment of the elongated member 60 may be hollow. An interior-facing side refers to an external surface of the hollow elongated member 60 that faces away from the exterior of the frame 18 and toward the cavity 19. It is not to be construed as any of the internal surfaces within the hollow elongated member 60.

Openings 68 are positioned on the recesses 66 of the elongated member 60 and are adapted to be aligned with the frame attachment points 48 of a corner piece 12. One or more inserts 70 are positioned along the recesses 66 for securing a panel 16 to the rail 14. The insert 70 may be a threaded insert for receiving a fastener. The recess 66 further includes a slot 74 for receiving a sealing feature.

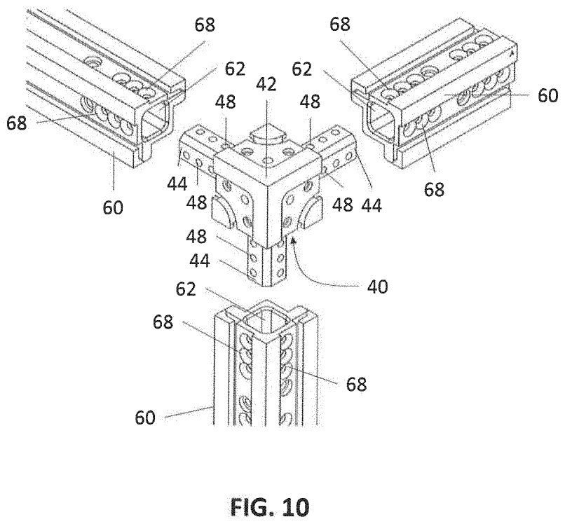

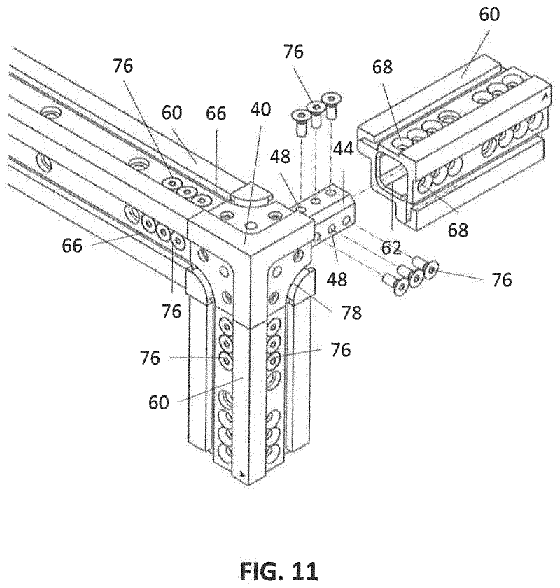

FIGS. 10 and 11 illustrate the assembly of a plurality of rails 14 to a corner piece 12. In the embodiment shown, the opposing end of each elongated member 60 includes an opening 62 that functions as a female end to be mated with the corner piece 12. The central block 40 has a post 44 on a plurality of its faces 42 that functions as a male end to be inserted into the opening 62 of the elongated member 60.

As seen in FIG. 11, the frame attachment points 48 and the openings 68 overlap when the male and female ends are mated. The frame attachment point 48 may be a threaded insert for receiving fasteners 76. When the rail 14 and corner piece 12 are mated, fasteners 76 are inserted through the opening 68 and fastened to the frame attachment point 48 to secure the rail 14 to the corner piece. Slots 54 and 74 of the corner piece 12 and rail 14, respectively, form a continuous channel 78 for receiving a sealing feature. Similarly, the recess 50 of central block 40 and the recess 66 of elongated member 60 form a continuous recess when mated, wherein the continuous recess is adapted to receive the corners and edges of a panel 16.

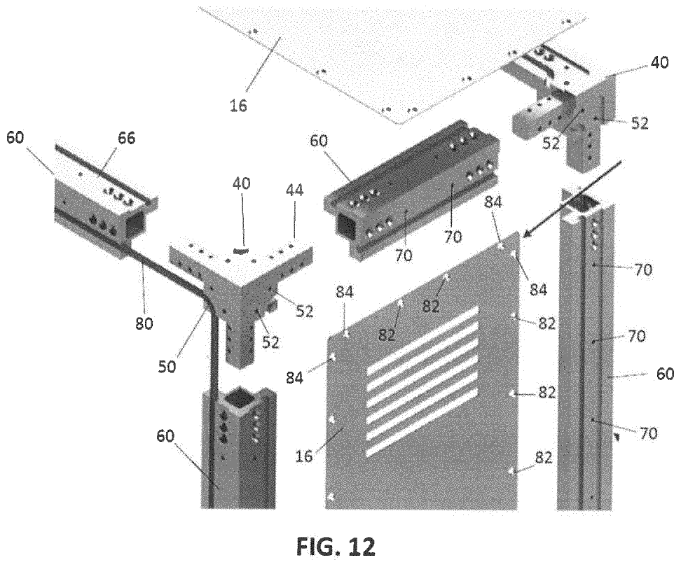

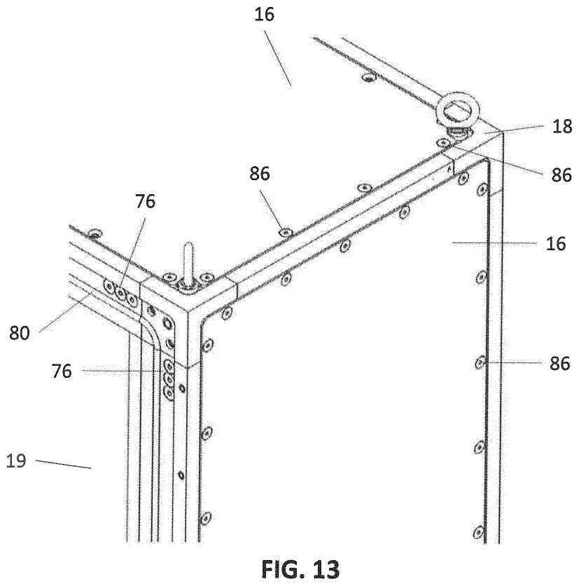

The assembly of the frame and panels are shown in FIGS. 12 and 13. In this embodiment, the panels 16 are inserted into the continuous recesses formed by the recesses 50 and 66 of the central blocks 40 and the elongated members 60. A sealing feature 80 is inserted into the channels 78 formed by the slots 54 and 74 of the central blocks 40 and elongated member 60. In one embodiment, the sealing feature 80 is a gasket. A single gasket may be used to both shield from environmental hazards and electromagnetic interference. For example, the single gasket may act as a water sealant preventing water ingress into the cavity 19.

Once the panel 16 is inserted, the panel 16 covers the sealing feature 80 and fasteners 76 used to secure the corner pieces 12 and rails 14. Thus, even though the fasteners 76 are positioned on the exterior faces of the posts 44 and elongated members 60, they are covered by the panel 16 and are no longer exposed to the exterior environment once the panel 16 is installed. Moreover, positioning the fasteners 76 on the exterior facing sides and concealing them with the panels 16 prevents the fasteners 76 from coming loose, particularly in environments where significant movement/vibrations are a concern.

The panels 16 include a set of edge openings 82 that overlap with the inserts 70 on the rail 14 and a set of corner openings 84 that overlap with the holes 52 on the corner piece 12. Fasteners 86 are inserted through these openings to secure the panel 16 to the frame 18. FIG. 12 provides a comparison of one side without a panel wherein the cavity 19 is exposed and two other sides wherein a panel is installed. The fasteners 76 in view without the panel installed are concealed by the panels 16 on the other two sides.

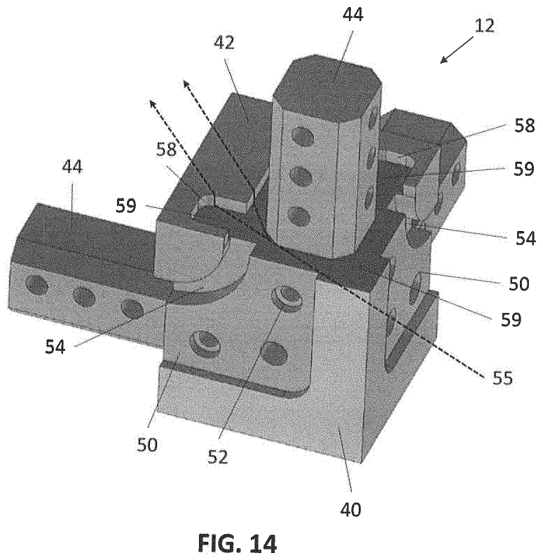

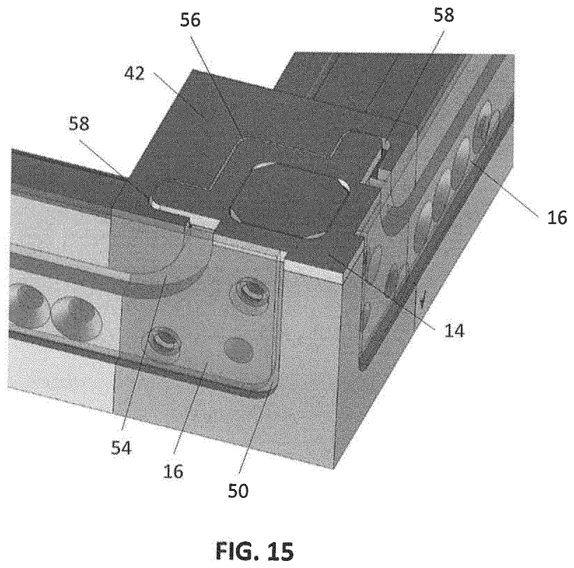

FIGS. 14 and 15 are directed to another embodiment of corner piece 12 and rail 14 with improved water sealing configurations. FIGS. 14 and 15 show a corner piece 12 with a groove 56 configured for a sealant to be applied within. The groove 56 is formed substantially around the male end of the corner piece 12. Grooves 56 may be provided for each post 44 on the corner piece 12. The groove 56 may be shaped substantially similarly to a rail 14 to provide sealant along the faying surface of the corner piece 12; for example, the groove 56 may further include extended regions 58 to provide improved water sealing along the faying surface when mated with a rail 14. FIG. 15 illustrates a cutaway view of the rail 14 inserted into the groove 56. The slots 54 remain free of sealant to accept a gasket or other sealing feature 80. The groove 56 prevent water ingress into the cavity by forming several 90° angles 55 that serve to impede water flow. When applied, the sealant acts as a further stop to prevent water from passing through the faying surface between the corner piece 12 and rail 14.

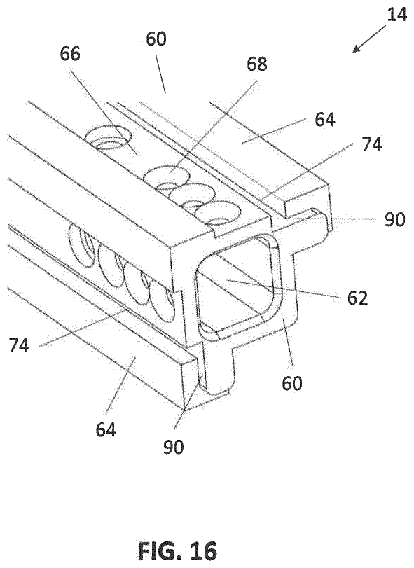

As shown in FIG. 16, the rail 14 comprises an elongated member 60 with appendages 64 and a recess 66 on each exterior-facing side. Each appendage 64 includes a slit 90 on each end that is continuous with a slot 74 that is adapted to mate with the extended regions 58 of the corner piece 12 and formed a sealed faying surface with the sealant 59.

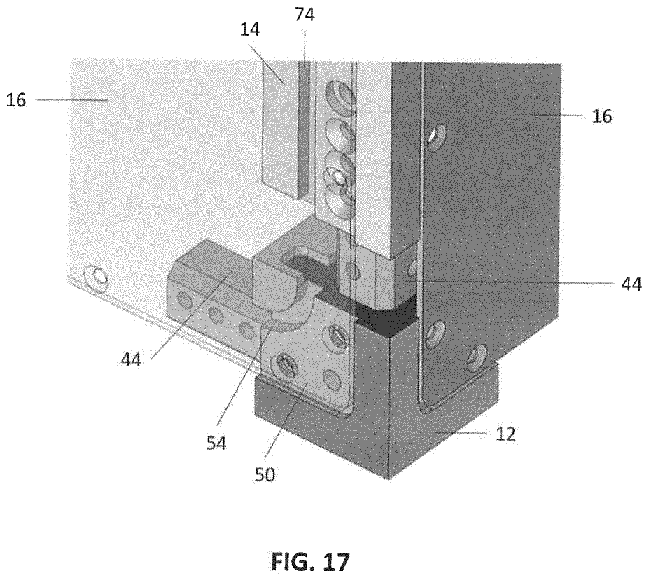

FIG. 17 shows the corner piece 12 and the rail 14 mating with a configuration that improves water sealing. The panels 16 are transparent in FIG. 17 for clarity. The post 44 of the corner piece 12 is inserted into the opening 62 of rail 14. The resulting configuration provides improved water sealing capabilities by obstructing water flow with several 90° turns 55 (seen in FIG. 14) and preventing water from penetrating the interface between the corner piece 12 and the rail 14. Moreover, the sealant provides additional protection from water ingression. Sealant may be applied on at least a portion of the surface of the groove 56. As the rail 14 is mated to the corner piece 12, the sealant may squeeze into the cracks of the groove 56 between the rail and corner piece. Excess sealant on the exterior may be cleaned prior to installing panel. Thus, any water attempting to enter would need to make two 90° turns and also bypass the sealant once the corner piece 12 and rail 14 are fully mated in order to gain entry into the cavity of the enclosure.

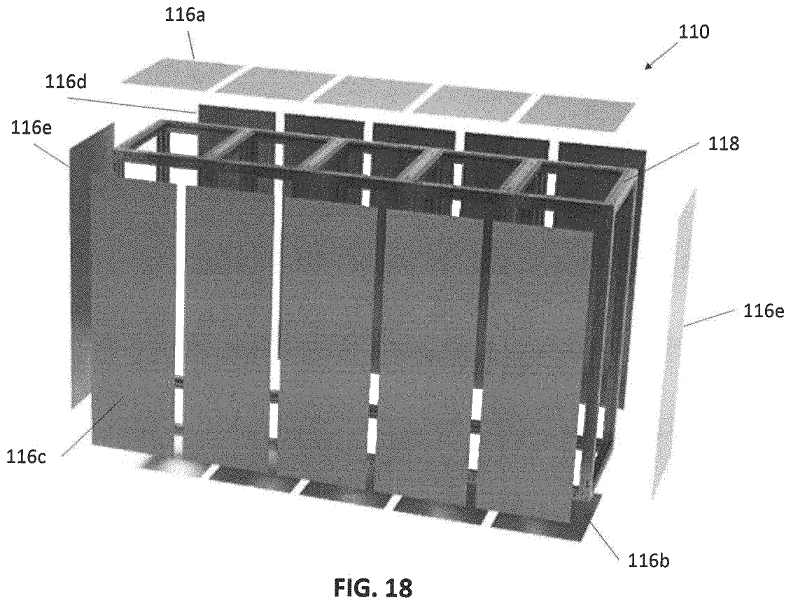

FIG. 18 illustrates another embodiment of a modular enclosure system 110. The top and bottom of the enclosure each comprise a plurality of panels 116a and 116b, respectively. The front and rear of the enclosure each comprises a plurality of panels 116c and 116d, respectively. Each side of the enclosure comprises a single panel 116e. This embodiment illustrates the modular feature of the system described herein, wherein the size of the enclosure may be adjusted by installing additional corner pieces, rails and panels where needed. Thus, in other embodiments, the sides may also comprise a plurality of panels. The size of the enclosure system 10 may also be dependent on the various sizes of the rails, corner pieces and panels provided, which may vary.

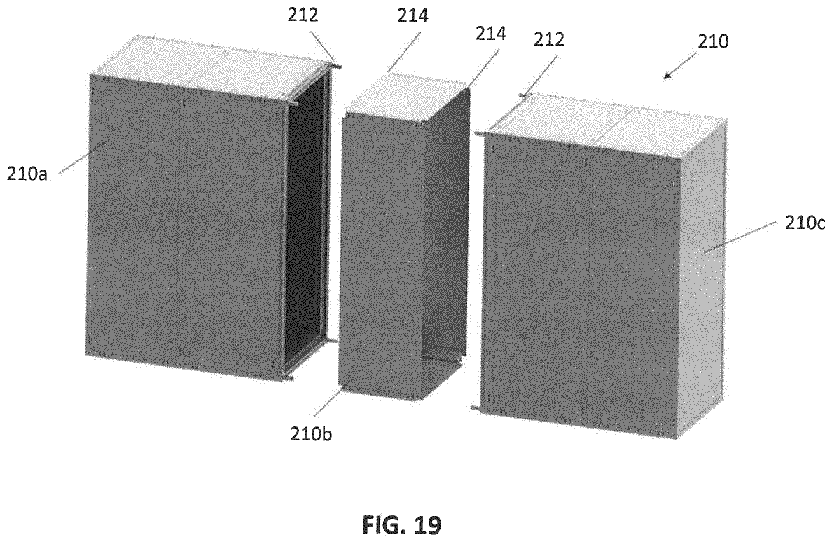

Due to the modularity of the enclosure system, the frame may be easily assembled, fully or partially disassembled, and modified as needed. In some embodiments, the enclosure system may be assembled as a standalone configuration. In other embodiment, the enclosure system 210 may have a multi-bay configuration comprising a plurality of sections that may be easily removable. FIG. 19 depicts one embodiment, wherein the enclosure system 210 comprises a first section 210a, a second section 210b, and a third section 210c. The sections may be combined by inserting the male ends of the corner pieces 212 into the female ends of the rails 214.

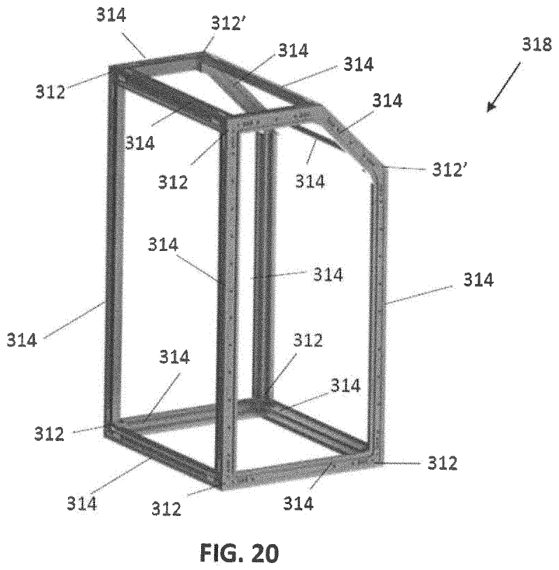

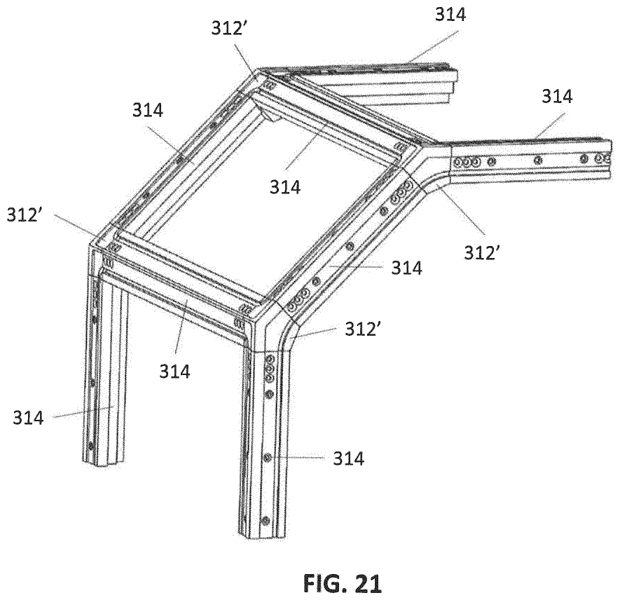

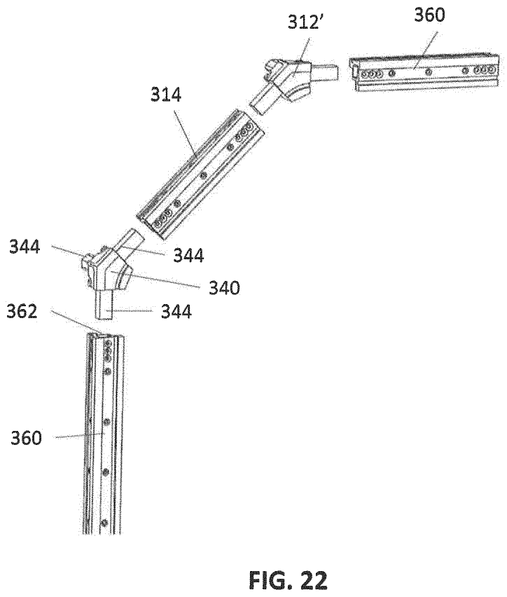

The frame of the enclosure system is not limited to a rectangular configuration. For example, FIGS. 20-22 provide one embodiment wherein the frame 318 adopts a non-rectangular configuration, wherein the top portion of the frame 318 includes an angled area. FIG. 21 shows an enlarged view of the frame 318 wherein several rails 314 are positioned at obtuse angles instead of at right angles. The frame 318 utilizes an embodiment of corner pieces 312′ wherein the corner piece 312′ is a pentagonal-shaped block 340 wherein two of the posts 344 are positioned at an obtuse angle with respect to each other. The rails 314 may comprise elongated members 360 with an opening 362 for receiving the posts 344 of the corner piece 312′. The frame 318 may also include corner pieces 312 wherein each male end is angled at a right angle with respect with one another.

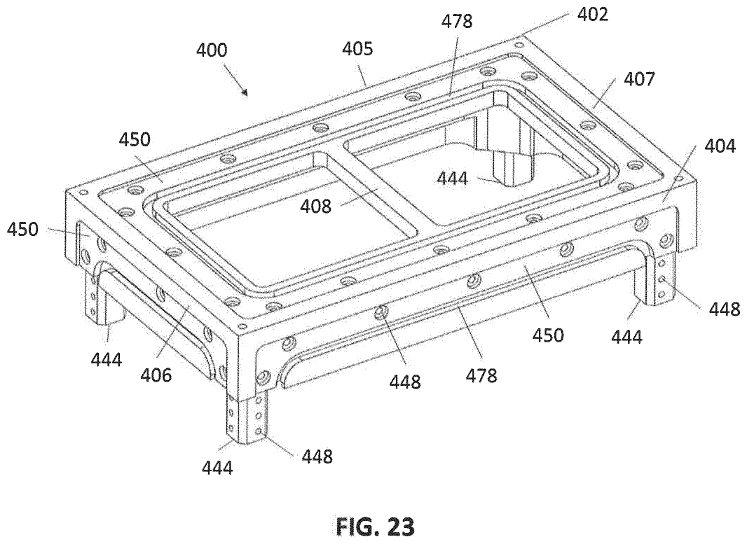

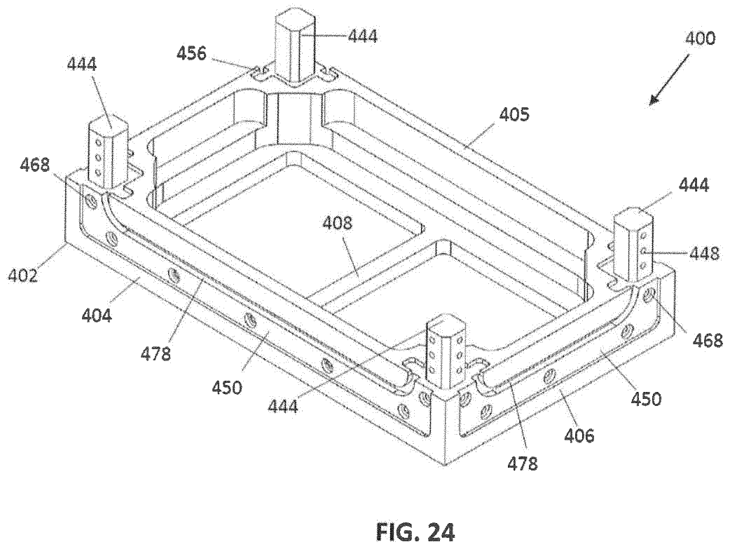

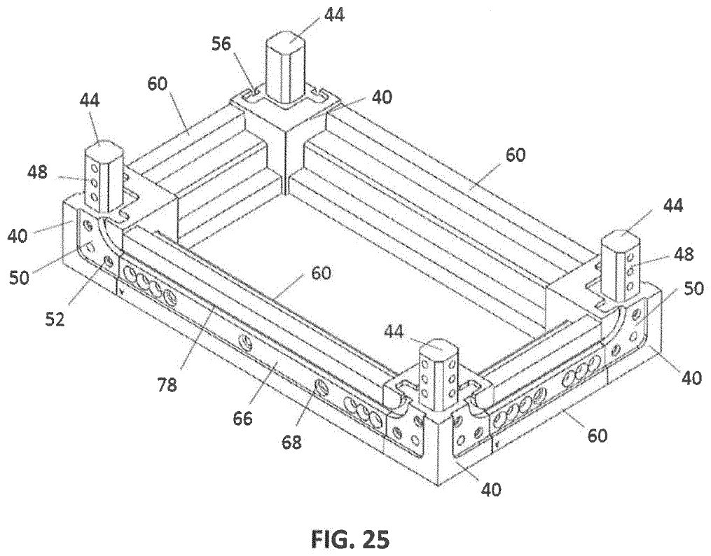

In some embodiments, one or more of the components may be manufactured as a single machined part. For example, one or more corner pieces may be integrated with one or more rail pieces to form a single integrated part to be used for assembling a frame. FIGS. 23 and 24 illustrate one embodiment wherein the single integrated part is an end cap 400. FIG. 25 illustrates an end cap formed from a set of corner pieces 40 and elongated members 60 (shown in FIGS. 5-8) for comparison with the end cap 400 in FIGS. 23 and 24. The end cap 400 is comprised of an end cap frame 402 having a front face 404, a rear face 405, and side faces 406. A top face 407 is formed from the front, rear and side faces. The end cap frame 402 further includes a crossbar 408 for providing additional structural stability. Unlike the end cap assembly shown in FIG. 25, end cap 400 shown in FIGS. 23 and 24 has a uniform frame with no seams between the corners and rails.

Posts 444 forming the male end for receiving and mating with a rail are positioned at each corner of the end cap frame 402. The rails may comprise independent elongated members 60 (such as shown in FIGS. 8 and 9) or provided by another integrated part. Each post 444 also includes frame attachment points 448 for fastening a rail to the post 444. Each face includes a recess 450 for receiving a panel. The recesses include openings 468 for fastening panels to the end cap frame 400. A continuous channel 478 is provided in each recess 450 for receiving a sealing feature such as a gasket.

The components herein are preferably comprised of aluminum. The panel may be comprised of a 5000-series aluminum. Since the corner pieces and rails are not welded, stress corrosion cracking due to welding the joints is not a concern and thus higher strength aluminum may be used. The 6000 series aluminum provides higher strength than the 5000 series while also being more conducive to extrusion compared to 7000 series aluminum. Thus in preferred embodiments, the rails 14 are extruded with a 6000 series aluminum, such as 6061T6 and the corners 12 are machined from the same.

Depending on the configuration, the enclosures may be capable of carrying payloads of up to 2,300 pounds per assembly under 20G load conditions using Finite Element Analysis (FEA) such as the Solidworks Simulation add-on. Applicant has discovered that the payload weight capacity for the enclosures herein is correlated with the number of attachment points of the frame and by changing the attachment points of the internal payload to the frame and the frame to the mounting foundation. More particularly, the payload weight capacity increases with increasing attachment points both between the payload and frame and between the frame and mounting foundation.

Although the present approach has been illustrated and described herein with reference to preferred embodiments and specific examples thereof, it will be readily apparent to those of ordinary skill in the art that other embodiments and examples may perform similar functions and/or achieve like results. All such equivalent embodiments and examples are within the spirit and scope of the present approach.

We claim:

1. A modular enclosure system comprising:
a corner piece having a plurality of faces;
a plurality of rails whereby each rail is adapted to mate with the corner piece and once mated is secured at one or more frame attachment points on the corner piece and the rail to form a frame; and
a panel adapted to be secured to the rails and the corner piece when mated and secured, wherein the panel conceals the frame attachment points when the panel is secured to the rails and the corner piece,
wherein each rail has an exterior-facing side that faces away from the frame when formed and an interior-facing side positioned within a cavity formed by the frame, whereby the fasteners securing the rails to the corner piece are positioned on the exterior-facing sides of the rails.

2. The modular enclosure system of claim 1 further including a sealing feature adapted to be installed on the corner piece and the rails.

3. The modular enclosure system of claim 2, wherein the sealing feature is a gasket adapted to prevent water from entering the frame and to shield from electromagnetic interference.

4. The modular enclosure system of claim 2, wherein one or more faces of the corner piece has a male end and the rail has a female end whereby the rail is adapted to mate with the corner piece by inserting the male end into the female end.

5. The modular enclosure system of claim 4, wherein the corner piece comprises a central block with a set of posts, each post having an exterior-facing side and an interior-facing side, the exterior-facing side of each facing away from the frame when formed and the interior-facing side of the post positioned within a cavity formed by the frame, each post positioned on a face of the central block, each post adapted to be inserted into the female end of the rail and secured with a fastener on the exterior-facing side of the post, whereby the posts are positioned at right angles to one another.

6. The modular enclosure system of claim 5 further including a recess on one or more faces of the corner piece unoccupied by a post, the recess adapted to receive a corner of the panel and a set of holes on each recess adapted to fasten the corner of the panel onto the corner piece.

7. The modular enclosure system of claim 6 further including a slot on the recess for receiving the sealing feature.

8. The modular enclosure system of claim 4, wherein each rail comprises an elongated member with an opening on each end for receiving the male end of the corner piece, the elongated member having an exterior-facing side and an interior-facing side whereby the elongated member is adapted to be secured to the male end of the corner piece on the exterior-facing side of the rail with a fastener.

9. The modular enclosure system of claim 8, wherein each rail is hollow.

10. The modular enclosure system of claim 8 further including a set of appendages on the rail that are orthogonal to one another.

11. The modular enclosure system of claim 10 further including a slot on an exterior face of each appendage for receiving a sealing feature.

12. The modular enclosure system of claim 10, wherein the slot on the rails and the slot on the corner piece are adapted to mate to form a continuous channel for receiving the gasket when the corner piece and the rails are attached.

13. The modular enclosure system of claim 4, wherein the male end of the corner piece and the female end of the rail are adapted to be secured by fasteners when the male end is inserted into the female end.

14. The modular enclosure system of claim 13, wherein the male end uses threaded inserts on an exterior-facing side to receive the fasteners.

15. The modular enclosure system of claim 4 further including a groove on one or more faces of the corner piece for receiving a sealant to prevent water from entering the frame when the corner piece is mated to the rail.

16. The modular enclosure system of claim 15 further including one or more ridges in the groove wherein each ridge is configured to prevent water from entering the frame by creating at least two 90° turns within the groove.

17. The modular enclosure system of claim 1, wherein the corner piece is adapted to be secured to each rail on a first and second face.

18. A weld-free enclosure constructed from a modular enclosure system, the enclosure comprising:
one or more corner pieces;
a plurality of rails mated with the corner piece forming a frame, wherein the rails are secured to the corner piece by fasteners;
a panel secured to the rails and the corner piece, the panel concealing the fasteners of the rails and the corner piece;
wherein each rail has an exterior-facing side and an interior-facing side, the exterior-facing side facing away from the frame and the interior-facing side positioned within a cavity formed by the frame, whereby the fasteners securing the rails to each corner piece are positioned on the exterior-facing sides of the rails.

19. The weld-free enclosure of claim 18 comprising at least eight corner pieces.

20. The weld-free enclosure of claim 18, wherein the corner piece has a male end and the rail has a female end whereby the rail is adapted to mate with the corner piece by inserting the male end into the female end.

21. The weld-free enclosure of claim 18 further including a sealing feature installed on the corner piece and the rails and adapted to prevent water from entering the frame and shield from electromagnetic interference.

22. The weld-free enclosure of claim 21, wherein the sealing feature is a gasket inserted into a continuous channel formed by the corner piece and the rails.
